(19) United States
(12) Patent Application Publication
(10) Pub. No.: US 2010/0059760 A1
(43) Pub. Date: Mar. 11, 2010

(54) GALLIUM NITRIDE-BASED COMPOUND SEMICONDUCTOR LIGHT EMITTING DEVICE AND PROCESS FOR ITS PRODUCTION

(75) Inventor: Hisayuki Miki, Ichihara-shi (JP)

Correspondence Address: SUGHRUE MION, PLLC, 2100 PENNSYLVANIA AVENUE, N.W., SUITE 800, WASHINGTON, DC, 20037, US

(73) Assignee: Showa Denko K.K., Minato-ku, Tokyo (JP)

(21) Appl. No.: 12/441,074

(22) PCT Filed: Dec. 20, 2007
(86) PCT No.: PCT/JP2007/075228

§ 371 Date: Mar. 12, 2009

(30) Foreign Application Priority Data
Dec. 20, 2006 (JP) 2006-343059
Mar. 22, 2007 (JP) 2007-074779

(51) Int. Cl. H01L 33/00

(52) U.S. Cl. 257/76; 438/46; 257/E33.023; 257/E33.005

(57) ABSTRACT

It is an object of the present invention to provide a gallium nitride-based compound semiconductor light emitting device with high light emission output and low driving voltage.

The gallium nitride-based compound semiconductor light emitting device of the present invention is a gallium nitride-based compound semiconductor light emitting device characterized by comprising an n-type semiconductor layer, a light emitting layer and a p-type semiconductor layer, composed of gallium nitride-based compound semiconductors, stacked in that order on a substrate, with a negative electrode and positive electrode provided on the n-type semiconductor layer and p-type semiconductor layer, respectively, the positive electrode being composed of a conductive transparent oxide material, wherein a layer containing a compound with a Ga—O bond and/or an N—O bond is present between the p-type semiconductor layer and positive electrode.

### TECHNICAL FIELD

The present invention relates to a gallium nitride-based compound semiconductor light emitting device and to a process for its production, and more particularly it relates to a gallium nitride-based compound semiconductor light emitting device with high light emission output and low driving voltage, and to a process for its production.

### BACKGROUND ART

Gallium nitride-based compound semiconductor light emitting devices have an n-type semiconductor layer and p-type semiconductor layer situated on either side of a light emitting layer, with a current being introduced through an negative electrode and positive electrode formed in contact with each to produce light emission.

The negative electrode is formed by stacking one or more metal thin-film layers on the n-type semiconductor layer exposed by etching from above using an etching method. The positive electrode is composed of a conductive film formed over the entirety of the p-type semiconductor layer and a metal multilayer film (bonding pad) formed on one region thereof. The conductive film is formed for distribution of current from the metal multilayer film across the entire p-type semiconductor layer. This is because it is a characteristic of gallium nitride-based compound semiconductor materials to have low diffusion of current in the transverse direction of the material films. That is, with the absence of a conductive film, current is only introduced into the p-type semiconductor layer region directly under the metal multilayer film, thus resulting in non-uniform current supply to the light emitting layer. The light from the light emitting layer is therefore blocked from the metal thin-film electrode that serves as the negative electrode, and cannot be released to the outside. It is for this reason that a conductive film is used as a current diffusion layer so that the current from the metal multilayer film is spread across the entire p-type semiconductor layer. The conductive film must therefore be optically transparent in order to ensure that the emitted light is released to the outside. Therefore, the conductive film used in a gallium nitride-based compound semiconductor light emitting device is usually a transparent conductive film.

Conventional positive electrode conductive films have a construction with a combination of Ni or Co oxide and Au as a contact metal for contact with the p-type semiconductor layer (for example, see Japanese Patent No. 2803742). Recently, constructions with increased optical transparency have been employed, by using an oxide with higher conductivity such as an ITO film as the metal oxide to form a thin contact metal film, or omitting the contact metal (for example, see Japanese Unexamined Utility Model Application Publication No. 6-38265).

Since layers composed of conductive transparent materials such as ITO films have superior optical transparency compared to Ni or Co oxide layers, it is possible to increase the film thickness without impairing the light extraction. Film thicknesses in the range of 10-50 nm are used with Ni or Co oxide layers, whereas layer thicknesses of 200-500 nm are used with conductive transparent films such as ITO films.

The advantages of using a conductive transparent film such as an ITO film as the positive electrode conductive film in a gallium nitride-based compound semiconductor light emitting device include high light transmittance compared to conventional positive electrode conductive films, and high light emission output for introduction of the same current. However, despite being conductive films, their contact resistance with p-type semiconductor layers is high compared to conventional positive electrode conductive films, and the side-effect of increased driving voltage during use is therefore a common problem.

Techniques for forming interlayers between p-type semiconductor layers and transparent conductive films have been disclosed.

For example, the method disclosed in U.S. Pat. No. 6,078,064 forms a p⁺ layer with an increased Mg content on the p-type semiconductor layer as the uppermost surface layer of the device structure. In some cases a p-type In_{0.1}Ga_{0.9}N layer is formed, as in the publication K-M Chang et al., Solid-State Electronics 49 (2005), 1381.

As a result of much diligent research by the present inventors, however, it has been found that such interlayers require severe conditions that hamper growth of satisfactory crystals, and therefore they have not been utilized in industry. For example, formation of a p⁺ layer at the final stage of the wafer results in residue of Mg in the furnace, which affects subsequent epitaxial growth. Even when a p-type In_{0.1}Ga_{0.9}N layer is finally formed into a film, the Mg is not easily incorporated into the crystals with growth at low temperatures that allow formation of In_{0.1}Ga_{0.9}N layers, and therefore a large amount of Mg must be circulated through the furnace. This has tended to produce the same effect as when forming the p⁺ layer.

Techniques utilizing Ga₂O₃ as the electrode for p-type gallium nitride-based compound semiconductors have also been disclosed (for example, see Japanese Unexamined Patent Publication No. 2006-261358). However, Ga₂O₃ has lower conductivity than ITO, and when a transparent electrode is constructed of this material alone the spread of current is insufficient, and problems have resulted, such as increased driving voltage and reduced light emission output due to a limited emission region.

### DISCLOSURE OF THE INVENTION

An object of the present invention is to solve the problems mentioned above and to provide a gallium nitride-based compound semiconductor light emitting device with high light emission output and low driving voltage, as well as a process for its production.

The present inventors have discovered that when an electrode composed of a conductive transparent material is to be contacted with a p-type gallium nitride-based compound semiconductor layer, it is possible to reduce the contact resistance by forming a layer containing a compound with a Ga—O bond and/or N—O bond between them, and we have further discovered several production processes for obtaining the structure, whereupon the present invention has been completed.

Specifically, the present invention provides the following.

(1) A gallium nitride-based compound semiconductor light emitting device comprising an n-type semiconductor layer, a light emitting layer and a p-type semiconductor layer, composed of gallium nitride-based compound semiconductors, in that order on a substrate, the n-type semiconductor layer and p-type semiconductor layer being provided with an negative electrode and positive electrode, respectively, and the positive electrode being composed of a conductive and transparent oxide material, the light emitting device being characterized in that a layer containing a compound with a Ga—O bond and/or an N—O bond is situated between the p-type semiconductor layer and the positive electrode.

(2) A gallium nitride-based compound semiconductor light emitting device according to (1) above, wherein the oxide material is at least one type selected from the group consisting of ITO, IZO, AZO and ZnO.

(3) A process for production of a gallium nitride-based compound semiconductor light emitting device wherein a gallium nitride-based compound semiconductor light emitting device is produced by forming an n-type semiconductor layer, a light emitting layer and a p-type semiconductor layer, composed of gallium nitride-based compound semiconductors, in that order on a substrate, and forming an negative electrode and positive electrode composed of a conductive and transparent oxide material, on the formed n-type semiconductor layer and p-type semiconductor layer, respectively, the process being characterized by comprising a step of producing a layer containing a compound with a Ga—O bond and/or an N—O bond on the surface of the p-type semiconductor layer, after the step of forming the positive electrode.

(4) A process for production of a gallium nitride-based compound semiconductor light emitting device according to (3) above, wherein the step of producing a layer containing a compound with a Ga—O bond and/or an N—O bond on the surface of the p-type semiconductor layer is heat treatment at a temperature of 300° C. or higher.

(5) A process for production of a gallium nitride-based compound semiconductor light emitting device according to (4) above, wherein the heat treatment is carried out in an oxygen-containing atmosphere.

(6) A process for production of a gallium nitride-based compound semiconductor light emitting device wherein a gallium nitride-based compound semiconductor light emitting device is produced by forming an n-type semiconductor layer, a light emitting layer and a p-type semiconductor layer, composed of gallium nitride-based compound semiconductors, in that order on a substrate, and forming an negative electrode and positive electrode composed of a conductive and transparent oxide material, on the formed n-type semiconductor layer and p-type semiconductor layer, respectively, the process being characterized by comprising a step of producing a layer containing a compound with a Ga—O bond and/or an N—O bond on the surface of the p-type semiconductor layer, after the step of forming the p-type semiconductor layer and before the step of forming the positive electrode.

(7) A process for production of a gallium nitride-based compound semiconductor light emitting device according to (6) above, wherein the step of producing a layer containing a compound with a Ga—O bond and/or an N—O bond on the surface of the p-type semiconductor layer comprises heat treatment for at least 1 minute at a temperature of 700° C. or higher in an ammonia-free atmosphere, and exposure to an oxygen-containing atmosphere either during or after the heat treatment.

(8) A process for production of a gallium nitride-based compound semiconductor light emitting device according to (7) above, wherein the heat treatment is carried out for at least 5 minutes.

(9) A process for production of a gallium nitride-based compound semiconductor light emitting device according to (6) above, wherein the step of producing a layer containing a compound with a Ga—O bond and/or an N—O bond on the surface of the p-type semiconductor layer is a step of lowering the temperature after formation of the p-type semiconductor layer, where the carrier gas is composed of a gas other than hydrogen and the temperature is lowered in an atmosphere containing no introduced ammonia, and the step is followed by exposure to an oxygen-containing atmosphere.

(10) A lamp comprising a gallium nitride-based compound semiconductor light emitting device according to (1) or (2) above.

(11) An electronic device incorporating a lamp according to (10) above.

(12) A machine incorporating an electronic device according to (11) above.

If a conductive transparent oxide material as the positive electrode is placed in Ohmic contact with a p-type gallium nitride-based compound semiconductor layer, and a layer containing a compound with a Ga—O bond and/or an N—O bond is formed between them, it is possible to obtain satisfactory Ohmic contact without forming an interlayer that requires the conditions contaminating the furnace.

### BRIEF DESCRIPTION OF THE DRAWINGS

FIG. 1 is a schematic drawing showing a cross-section of a gallium nitride-based semiconductor light emitting device of the present invention.

FIG. 2 is a cross-sectional schematic drawing of the epitaxial stacked structure fabricated in Example 1.

FIG. 3 is a plan schematic view of the gallium nitride-based semiconductor light emitting device fabricated in Example 1.

FIG. 4 is a graph showing the fall in temperature after growth of the p-type semiconductor layer in Example 1.

FIG. 5 is a hard X-ray excited electron emission spectrum for Ga2p_{3/2}, measured using a sample obtained by forming a p-type semiconductor layer and ITO electrode in a gallium nitride-based semiconductor light emitting device according to the present invention.

FIG. 6 is a hard X-ray excited electron emission spectrum for N1s, measured using a sample obtained by forming a p-type semiconductor layer and ITO electrode in a gallium nitride-based semiconductor light emitting device according to the present invention.

FIG. 7 is a hard X-ray excited electron emission spectrum for Ga2p_{3/2}, measured from the p-type semiconductor layer side of the epitaxial stacked structure fabricated in Example 1.

FIG. 8 is a hard X-ray excited electron emission spectrum for N1s, measured from the p-type semiconductor layer side of the epitaxial stacked structure fabricated in Example 1.

### BEST MODE FOR CARRYING OUT THE INVENTION

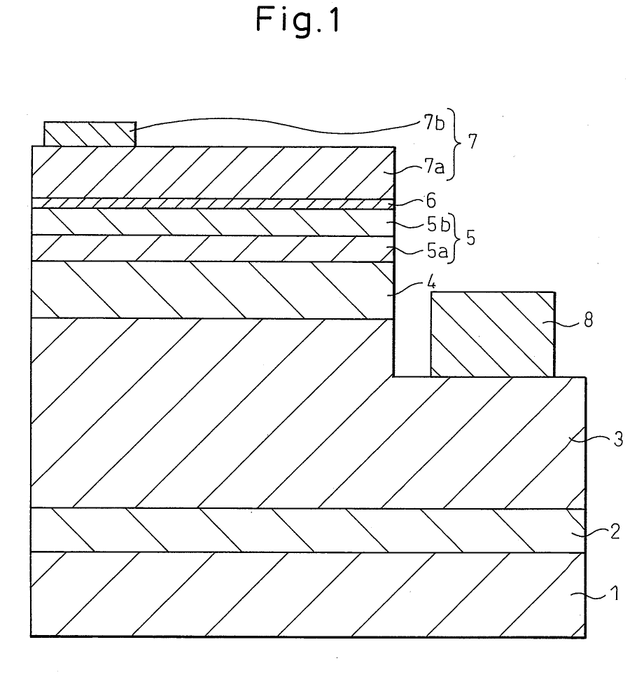

FIG. 1 is a schematic view showing the cross-section of a gallium nitride-based compound semiconductor light emitting device having an ITO positive electrode formed directly on a p-type semiconductor layer, according to the present invention. In this drawing, 7 is the positive electrode, which is composed of a transparent conductive film 7a made of ITO and a bonding pad layer 7b. The numeral 5 represents a p-type semiconductor layer, which is composed of a p-type clad layer 5a and a p-type contact layer 5b. The numeral 6 represents a layer containing a compound with a Ga—O bond and/or an N—O bond. Also, 1 is a substrate, 2 is a buffer layer, 3 is an n-type semiconductor layer, 4 is a light emitting layer and 8 is an negative electrode.

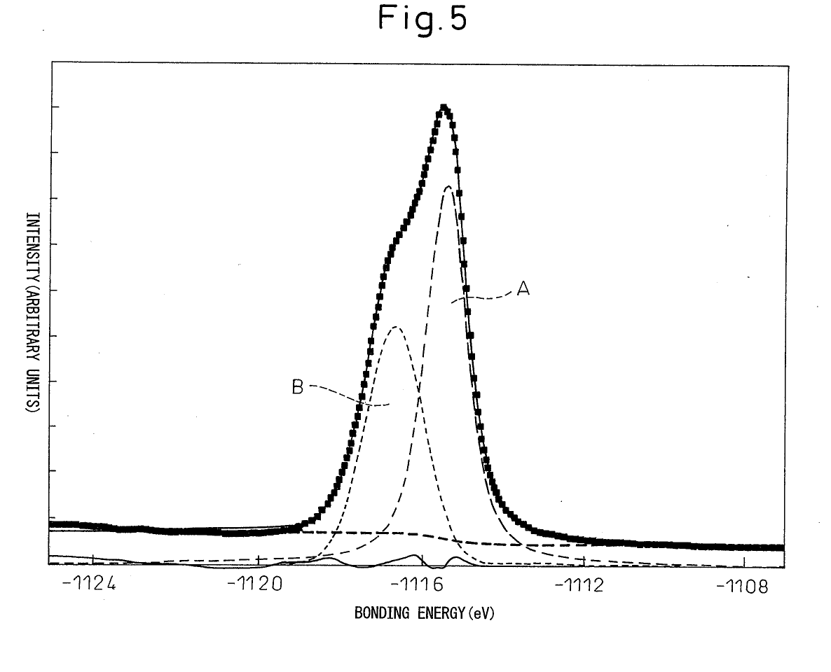

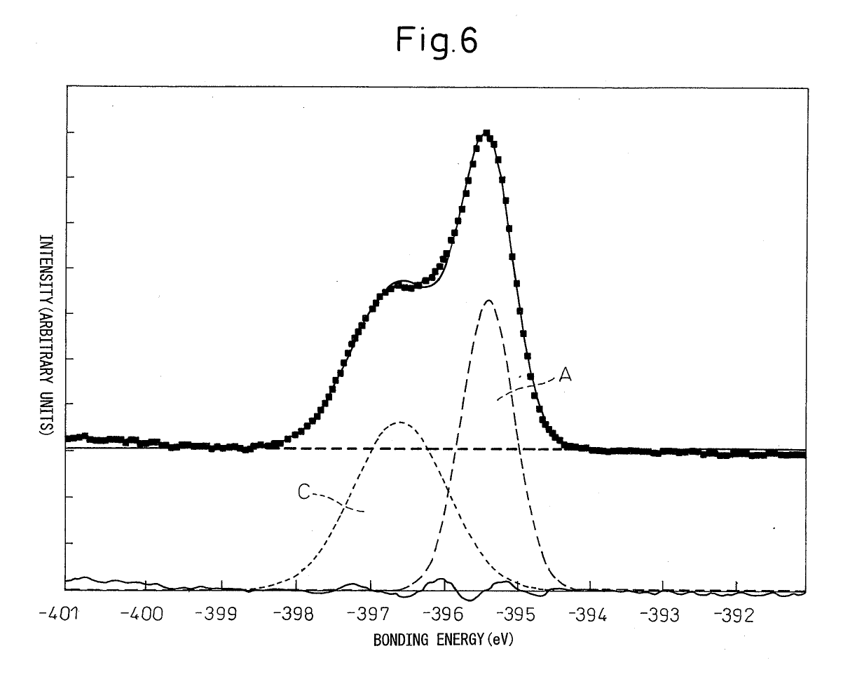

In Example 1 described hereunder, a sample having an electrode structure according to the present invention was prepared, and the region of the p-type gallium nitride-based compound semiconductor layer on which the ITO has been formed was analyzed by hard X-ray photoelectron spectroscopy (emitted light energy=5948 eV) in the SPring-8, giving the results shown in FIG. 5 and FIG. 6. The photoelectron escape depth was approximately 7 nm. This analysis method can obtain information regarding the chemically bonded state of the ITO and the gallium nitride-based compound semiconductor in contact with the ITO. FIG. 5 shows the analysis results for the Ga 2p_{3/2} peak, and FIG. 6 shows the analysis results for the N is peak.

The form of the spectrum shown in FIG. 5 indicates that the peak consists of two overlapping components, and analysis of the peaks by the peak fitting method reveals a peak attributed to Ga—N bonds (peak A in FIG. 5) and a peak attributed to Ga—O bonds (peak B in FIG. 5). The Ga—N bond is from the p-type gallium nitride-based compound semiconductor GaN. The Ga—O bond is from the gallium oxide (GaOₓ). This indicates that a GaOₓ layer with a thickness of several nm has been formed at the interface between ITO and GaN.

The form of the spectrum shown in FIG. 6 also indicates that the peak consists of two overlapping components, and fitting reveals a split due to the presence of the component derived from the Ga—N bonds (peak A in FIG. 6) and the component derived from the N—O bonds (peak C in FIG. 6). The film thickness of the component derived from the N—O bonds is approximately equivalent to the film thickness of the GaOₓ layer, and it is clear that the complex oxide layer composed of Ga—N—O—Ga has been formed at the ITO/GaN interface.

These analyses demonstrate that the light emitting device fabricated in Example 1 described hereunder has a layer containing gallium oxide (GaOₓ) between the conductive transparent oxide ITO and the p-type GaN. A component with N—O bonds is also present.

In other words, a layer containing a compound with a Ga—O bond and/or an N—O bond according to the present invention is a layer that exhibits a peak attributed to Ga—O bonds and/or a peak attributed to N—O bonds in hard X-ray photoelectron spectroscopy (emitted light energy=5948 eV) analysis. The compound with a Ga—O bond may be, for example, a gallium oxide (GaOₓ) such as Ga₂O₃. Considering the presence of the compound with an N—O bond, the compound with a Ga—O bond and/or an N—O bond may be a complex oxide represented by Ga_{(2-y)}N_{y}O_{(3-3y)} (0≦y<1). When ITO or IZO is used as the positive electrode, complex oxides represented by GaₓIn_{y}NₓO_{(3-3z)} (x+y=2-z, 0≦z<1) may also be present, depending on the production conditions.

The thickness of the layer containing the compound with a Ga—O bond and/or an N—O bond may be determined by the following method.

The intensity of light propagating in the medium while damping is represented by I═I₀×Exp(−kl) [I₀: light intensity before damping, k: attenuation coefficient, l: distance propagated in medium]. Since the attenuation coefficient is unique to the medium, this allows calculation of the distribution of incident light intensity during damping and the distribution of light intensity emitted in the direction of observation during damping after the resultant excitation. An abundance ratio of bonds that satisfies the ratio of intensity of the two measured peaks may be determined by simulation, assuming an abundance ratio based on the above formula.

The film thickness of the layer containing the compound with a Ga—O bond and/or an N—O bond is preferably between 1 nm and 100 nm. It is more preferably between 5 nm and 20 nm.

The layer containing the compound with a Ga—O bond and/or an N—O bond may have any composition, but the layer preferably consists of gallium nitride crystals in which a compound with a Ga—O bond and/or an N—O bond accounts for at least 50%.

The compound with the Ga—O bond and/or N—O bond may also be present in any form. It may be laminar, as well as insular or spotted. However, the contact area between the conductive transparent oxide layer and gallium nitride-based compound semiconductor layer is preferably large, and at least 50% of the surface area preferably consists of the compound with a Ga—O bond and/or an N—O bond. It is most preferably present in a laminar form between the conductive transparent oxide and gallium nitride-based compound semiconductor.

The method for forming the layer containing the compound with a Ga—O bond and/or an N—O bond between the conductive transparent oxide electrode layer and the layer composed of the gallium nitride-based compound semiconductor may be a method in which the p-type gallium nitride-based compound semiconductor is formed, and then the gallium oxide layer is formed separately. The method of film formation may be any common method such as sputtering, vapor deposition, CVD or the like.

However, different film-forming apparatuses must be prepared for methods of separate film formation, and this increases the cost of equipment while also lengthening the process.

Annealing may be mentioned as a method for fabricating the layer containing the compound with a Ga—O bond and/or an N—O bond. By annealing a conductive transparent oxide electrode film after film formation, it is possible to promote reaction between the electrode film and p-type semiconductor layer to form a layer containing the compound with a Ga—O bond and/or an N—O bond. The annealing temperature after the electrode film formation may be 300° C. or higher, preferably 400° C. or higher and most preferably 600° C. or higher. The annealing time is preferably between about 10 seconds and 30 minutes. The atmosphere gas in the gas phase during annealing may contain oxygen, nitrogen, argon or the like, or a vacuum may be used. It preferably contains oxygen.

After formation of the p-type semiconductor layer, annealing may be carried out before forming the conductive transparent oxide electrode film. It is known that nitrogen loss occurs when a gallium nitride-based compound semiconductor is annealed in an ammonia-free atmosphere at a temperature of 700° C. or higher. A surface with nitrogen loss and excess gallium can be exposed to an oxygen-containing atmosphere to form a layer containing the compound with a Ga—O bond and/or an N—O bond on the surface. An oxygen-containing atmosphere may be oxygen itself, or a mixed gas comprising oxygen and another gas may be prepared, or even air may be used. The temperature may be appropriately selected as the environment for exposure to oxygen, and room temperature may be suitable. The annealing may be carried out in an oxygen-containing atmosphere.

It is known that when gallium nitride has been heat treated, hydrogen dissociates from the crystals at the initial stage of the heat treatment process, and subsequent decomposition of the crystals results in dissociation of nitrogen (for example, see I. Waki, et al, J. Appl. Phys. 90, 6500-6504 (2001)). For the purpose of the present invention, it is necessary to promote decomposition of the crystals at the uppermost surface for dissociation of nitrogen element. Consequently, a certain length of time for holding during the heat treatment is necessary to initiate dissociation of nitrogen. Specifically, at least 1 minute of holding is necessary, and 5 minutes or longer is preferred.

However, different apparatuses must likewise be prepared for methods of separate annealing, and this increases the cost of equipment while also lengthening the process.

An effect similar to annealing can also be obtained by adjusting the atmosphere gas in the gas phase during temperature lowering after formation of the gallium nitride-based compound semiconductor.

The p-type gallium nitride-based compound semiconductor is formed at a high temperature of between 900° C. and 1200° C., using hydrogen, nitrogen or the like as the carrier gas and using ammonia and an organometallic material as the precursors. Upon completion of the film formation, the gas phase atmosphere is switched to a hydrogen-free atmosphere and supply of ammonia is stopped at a temperature of 700° C. or higher, to allow formation of a surface with excess gallium on the uppermost surface of the gallium nitride-based semiconductor. This surface can be exposed to an oxygen-containing atmosphere to form a layer containing the compound with a Ga—O bond and/or an N—O bond on the surface. An oxygen-containing atmosphere may be oxygen itself, or a mixed gas comprising oxygen and another gas may be prepared, or even air may be used. The temperature may be appropriately selected as the environment for exposure to oxygen, and room temperature may be suitable. That is, a layer containing the compound with a Ga—O bond and/or an N—O bond can be formed by simple exposure in air at room temperature. This method is the least expensive and without redundant steps, and is therefore the preferred method.

According to the present invention, the substrate 1 may be made of a known substrate material selected from among oxide single crystal substrates such as sapphire single crystal (Al₂O₃; A-plane, C-plane, M-plane, R-plane), spinel single crystal (MgAl₂O₄), ZnO single crystal, LiAlO₂ single crystal, LiGaO₂ single crystal, MgO single crystal or Ga₂O₃ single crystal, and non-oxide single crystal substrates such as Si single crystal, SiC single crystal, GaAs single crystal, AlN single crystal, GaN single crystal and boride single crystals such as ZrB₂. There are no particular restrictions on the plane direction of the substrate, and the off-angle may be selected as desired.

As gallium nitride-based semiconductors for the buffer layer, n-type semiconductor layer, light emitting layer and p-type semiconductor layer there are known semiconductors with various compositions represented by the general formula AlₓIn_{y}Ga_{1-x-y}N (0≦x≦1, 0≦y<1, 0≦x+y≦1). Semiconductors with various compositions represented by the general formula AlₓIn_{y}Ga_{1-x-y}N (0≦x≦1, 0≦y<1, 0≦x+y≦1) may also be used without any particular restrictions for gallium nitride-based semiconductors for the buffer layer, n-type semiconductor layer, light emitting layer and p-type semiconductor layer according to the present invention.

The method used for growing these gallium nitride-based semiconductors may be metal-organic chemical vapor deposition (MOCVD), molecular beam epitaxy (MBE), hydride vapor phase epitaxy (HVPE) or the like. MOCVD is preferred for easier composition control and increased productivity, but there is no limitation to this method.

When MOCVD is employed as the growth method for the semiconductor layer, the organometallic materials trimethylgallium (TMG) and triethylgallium (TEG) may be used as Ga sources, and trimethylaluminum (TMA) or triethylaluminum (TEA) may be used as the Al source. The precursor for In, which is a constituent precursor of the light emitting layer, may be trimethylindium (TMI) or triethylindium (TEI). As an N source there may be used ammonia (NH₃) or hydrazine (N₂H₄).

Si or Ge may be used as dopant materials for the re-type semiconductor layer. As Si precursors there may be used monosilane (SiH₄) or disilane (Si₂H₆), and as Ge precursors there may be used germane (GeH₄) or organic germanium compounds. Mg may be used as a dopant material in the p-type semiconductor layer. The Mg precursor may be biscyclopentadienylmagnesium (Cp₂Mg) or bisethylcyclopentadienylmagnesium ((EtCp)₂Mg), for example.

Semiconductor layers obtained by common MOCVD as the growth method will now be described.

(Buffer Layer)

As buffer layers there are known the low-temperature buffer layer disclosed in Japanese Patent No. 3026087 and the high-temperature buffer layer disclosed in Japanese Unexamined Patent Publication No. 2003-243302, but there is no restriction to using these buffer layers.

The substrate 1 used for growth may be any one selected from among those mentioned above, but a sapphire substrate will be used for the following explanation. The substrate is placed on an SiC film-attached graphite jig (susceptor) situated in a reaction space with variable temperature and pressure, and a hydrogen carrier gas and nitrogen carrier gas are fed into the location together with NH₃ gas and TMA. The SiC film-attached graphite jig is heated to the necessary temperature by induction heating with an RF coil, forming an AlN buffer layer on the substrate. The temperature is controlled to between 500° C. and 700° C. in order to grow an AlN low-temperature buffer, and then raised to about 1100° C. for crystallization. Growth of a high temperature AlN buffer layer may be accomplished by raising the temperature in one stage in a range of between 1000° C. and 1200° C., instead of heating in two stages. Growth of the buffer layer is not necessarily required when the aforementioned AlN single crystal substrate or GaN single crystal substrate is used, and an n-type semiconductor layer described hereunder may be directly grown on the substrate.

(n-Type Semiconductor Layer)

Various compositions and structures are known for n-type semiconductor layers as well, and any known compositions and structures may also be employed for the present invention. Normally, the n-type semiconductor layer will be composed of an underlying layer made of an undoped GaN layer, an n-type contact layer containing an n-type dopant such as Si or Ge and having a negative electrode formed thereon, and an n-type clad layer with a larger band gap energy than the light emitting layer. The n-type contact layer may serve as the n-type clad layer and/or underlying layer.

Following formation of the buffer layer, an underlying layer made of an undoped GaN layer is grown on the buffer layer. With a temperature of 1000-1200° C. and under pressure control, NH₃ gas and TMG are fed to the buffer layer together with a carrier gas. The amount of TMG fed is limited by the proportion with respect to the simultaneously flowing NH₃, but control to a growth rate of between 1 μm/hr and 3 μm/hr is effective for inhibiting crystal defects such as dislocations. The growth pressure is optimally in the range of 20-60 kP (200-600 mbar) in order to ensure the growth rate specified above.

An n-type contact layer is grown after growth of the undoped GaN layer. The growth conditions are the same as the growth conditions for the undoped GaN layer. The dopant is supplied together with the carrier gas, and the supply concentration is controlled by the proportion with respect to the TMG supply rate. In the present invention, specifying the composition of the p-type semiconductor layer as described hereunder can lower the driving voltage of a light emitting device comprising a positive electrode composed of an oxide material, but since the driving voltage is affected by the dopant concentration of the n-type contact layer, the dopant concentration of the n-type contact layer may be set according to the growth conditions for the p-type semiconductor layer. The dopant supply conditions may be an M/Ga ratio (M=Si or Ge) in the range of 1.0×10⁻³-6.0×10⁻³, in order to allow lowering of the driving voltage.

The film thicknesses of the undoped GaN layer and the dopant-containing n-type semiconductor layer are preferably each 1-4 μm, but there is no necessary limitation to this range. The film thicknesses of the undoped GaN layer and/or dopant-containing n-type semiconductor layer may be increased as a way of preventing propagation of crystal defects from the substrate and buffer layer to the upper layers, but this is not advisable since increasing the thickness induces warping of the wafer itself. In the present invention, it is preferred for the film thickness of each layer to be established within the range specified above.

(Light Emitting Layer)

Various compositions and structures are known for light emitting layers as well, and any known compositions and structures may also be employed for the present invention.

For example, a light emitting layer with a multiple quantum well structure is formed by alternate lamination of an n-type GaN layer as the barrier layer and a GaInN layer as the well layer. The carrier gas selected for use is N₂ or H₂. The NH₃ and TEG or TMG are supplied together with the carrier gas.

TMI is also supplied during growth of the GaInN layer. That is, the process involves intermittent supply of 1n while controlling the growth time. Since it is difficult to control the In concentration when H₂ is present in the carrier gas during growth of the GaInN layer, it is inadvisable to use H₂ as the carrier gas for this layer. The film thicknesses of the barrier layer (n-type GaN layer) and well layer (GaInN layer) are selected for conditions that result in the highest light emission output. The Group III precursor supply rate and growth time are appropriately selected upon determining the optimum film thickness. The amount of dopant in the barrier layer is also a condition that governs the level of driving voltage of the light emitting device, and the concentration is selected according to the growth conditions for the p-type semiconductor layer. Either Si or Ge may be used as the dopant.

The growth temperature is preferably between 700° C. and 1000° C., although there is no necessary limitation to this range. However, a high temperature during growth of the well layer will inhibit incorporation of In into the growing film, thus substantially hampering formation of the well layer. The growth temperature is therefore selected in a range that is not too high. According to the present invention, the growth temperature range for the light emitting layer is between 700° C. and 1000° C., but the growth temperatures for the barrier layer and well layer may be changed. The growth pressure is set in balance with the growth rate. The growth pressure is preferably between 20 kP (200 mbar) and 60 kP (600 mbar) according to the present invention, but there is no necessary limitation to this range.

The number of well layers and barrier layers is suitably between 3 and 7 for each, although there is no necessary limitation to this range. The light emitting layer is completed upon growth of the final barrier layer. The barrier layer prevents carrier overflow from the well layer while also acting to prevent re-dissociation of In from the final well layer during growth of the p-type semiconductor layer.

(p-Type Semiconductor Layer)

The p-type semiconductor layer will usually be composed of a p-type contact layer having a positive electrode formed thereover, and a p-type clad layer with a larger band gap energy than the light emitting layer. The p-type contact layer may also serve as the p-type clad layer.

The amount of p-type dopant in the p-type contact layer is preferably between 1×10¹⁸ cm^{˜3} and 1×10²¹ cm⁻³. The amount of Mg in the p-type contact layer can be controlled by appropriately adjusting the abundance ratio in the Ga and Mg gas phase circulated during growth. With MOCVD, for example, it may be controlled by the proportion of the Ga precursor TMG and the Mg precursor Cp₂Mg which are circulated.

For growth of the p-type semiconductor layer, first a p-type clad layer is stacked directly over the final barrier layer of the light emitting layer, and a p-type contact layer is stacked thereover. The p-type contact layer becomes the uppermost layer, and the conductive transparent oxide such as ITO forming part of the positive electrode is in contact therewith. GaN or GaAlN is preferably used for the p-type clad layer. During this time, layers with different compositions or lattice constants may be alternately stacked and the thicknesses of the layers and the dopant Mg concentrations may be varied.

Growth of the p-type contact layer is accomplished in the following manner. TMG, TMA and the dopant Cp₂Mg are fed onto the p-type clad layer together with a carrier gas (hydrogen or nitrogen, or a mixture thereof) and NH₃ gas.

The growth temperature during this time is preferably in the range of 980-1100° C. At a lower temperature than 980° C., a low-crystallinity epitaxial layer will form, thus increasing the film resistance due to crystal defects. At a higher temperature than 1100° C., the well layer, in the light emitting layer located thereunder, will be situated in a high temperature environment during the p-type contact layer growth process, potentially undergoing thermal damage. This can lower the intensity of the eventually formed light emitting device or reduce the intensity in resistance testing.

The growth pressure is not particularly restricted but is preferably no greater than 50 kP (500 mbar). This is because growth in this pressure range can produce a more uniform Al concentration in the in-plane direction of the p-type contact layer, thus facilitating control when growing a p-type contact layer with variation of the Al composition of the GaAlN as necessary. Under conditions with a higher pressure, reaction between the supplied TMA and NH₃ becomes dominant causing the TMA to be consumed during growth before it reaches the substrate, and making it difficult to obtain the desired Al composition. The same applies for Mg that is fed as the dopant. That is, if the growth conditions are below 50 kP (500 mbar), the Mg concentration distribution in the p-type contact layer will be homogeneous in the two-dimensional direction (the in-plane direction of the growth substrate), so that in-plane uniformity is achieved on the growth substrate.

It is known that the distribution of the Al composition and Mg concentration in the in-plane direction of the GaAlN contact layer varies depending on the carrier gas flow rate. However, it has been found that the in-plane uniformity of the Al composition and Mg concentration in the contact layer are more significantly affected by the growth pressure conditions than by the carrier gas conditions. Therefore, a growth pressure of no greater than 50 kP (500 mbar) and at least 10 kP (100 mbar) is most suitable.

That is, the growth rate Vgc of the p-type contact layer is preferably 10-20 nm/min and more preferably 13-20 nm/min under the aforementioned conditions for the growth temperature and growth pressure. The value of α(Mg/Ga) is preferably 0.75×10⁻²-1.5×10⁻² and more preferably 0.78×10⁻²-1.2×10⁻². Under these conditions, the Mg concentration of the p-type contact layer may be controlled to 1×10¹⁹-4×10²⁰ atoms/cm³, preferably 1.5×10¹⁹-3×10²⁰ atoms/cm³ and even more preferably 9×10¹⁹-2×10²⁰ atoms/cm³.

The film thickness of the p-type contact layer is preferably 50-300 nm and even more preferably 100-200 nm.

The growth rate is determined by measuring the film thickness of the p-type contact layer by TEM observation of the wafer cross-section or spectroscopic ellipsometry, and dividing it by the growth time. The Mg concentration of the p-type contact layer may be determined with an ordinary mass spectrometer (SIMS).

The negative electrode and positive electrode formed on the n-type contact layer and p-type contact layer will now be explained.

(Negative Electrode)

Various compositions and structures are known for negative electrodes as well, and any known compositions and structures may also be employed for the present invention. Various processes are also known for their production, and any such known processes may be employed.

The negative electrode-forming step may involve the following procedure, for example.

A known photolithography technique or ordinary etching technique may be used to form the negative electrode-forming side on the n-type contact layer. Such techniques allow etching from the uppermost layer of the wafer up to the location of the n-type contact layer, thus exposing the n-type contact layer at the negative electrode-forming regions. As negative electrode materials there may be used metal materials such as Al, Ti, Ni and Au, as well as Cr, W and V, as contact metals for contact with the n-type contact layer. In order to improve adhesiveness with the n-type contact layer, a multilayer structure may be used that comprises a combination of several contact metals selected from among the aforementioned metals. Using Au for the uppermost surface will result in satisfactory bonding properties.

(Positive Electrode)

According to the present invention, a conductive transparent oxide such as ITO, IZO, AZO or ZnO is used for the positive electrode.

Of these, ITO is a common conductive oxide, and the ITO composition is preferably 50%≦In<100% and 0%<Sn≦50%. Within these ranges it is possible to satisfy the stipulations of low film resistance and high light transmittance. Most preferred are In=90% and Sn=10%. The ITO may also contain Group II, III, IV or V elements as impurities.

The film thickness of the ITO film is preferably 50-500 nm. At less than 50 nm, the film resistance of the ITO film itself will be increased, resulting in higher driving voltage. Conversely, a greater thickness than 500 nm will lower the efficiency of light extraction to the top, resulting in a low light emission output.

The film-forming method for the ITO film may be a known vacuum vapor deposition method or sputtering method. Resistance heating systems and electron beam heating systems are used for heating in vacuum vapor deposition, but an electron beam heating system is preferred for vapor deposition of materials other than metals. There may also be used a method in which the starting compounds are liquefied and coated onto the surface, after which suitable treatment is carried out to form an oxide film.

The crystallinity of the ITO film is affected by the conditions in vapor deposition, but this is not limitative so long as the conditions are appropriately selected. When the ITO film is formed at room temperature, heat treatment will be necessary for transparency.

Since film formation by sputtering is in a high energy environment of plasma the p-type contact layer surface is susceptible to damage by the plasma, and therefore the contact resistance tends to be increased, but the film-forming conditions can be modified to reduce the effects on the p-type contact layer surface.

After formation of the ITO film, a bonding pad layer composed of a bonding pad section is formed on a portion of the surface. Together, these constitute the positive electrode. Various structures are known for bonding pad layer materials, and they may be used for the present invention as well, without any particular restrictions. There may be used the Al, Ti, Ni or Au of the negative electrode material, or Cr, W, V or the like, without any particular restrictions. However, it is preferred to use a material with satisfactory adhesiveness with the ITO film. The thickness must be sufficient so that the stress during bonding does not damage the ITO film. The uppermost layer is preferably a material such as Au that has satisfactory adhesiveness with the bonding ball.

The gallium nitride-based semiconductor light emitting device of the present invention may be provided with a transparent cover to produce a lamp, by means known in the technical field. The gallium nitride-based compound semiconductor light emitting device of the present invention may also be combined with a phosphor-containing cover to produce a white lamp.

Since a lamp made from a gallium nitride-based compound semiconductor light emitting device of the present invention has high light emission output and low driving voltage, electronic devices such as cellular phones, displays, panels and the like incorporating lamps made with this technology, or machines such as automobiles, computers or game devices incorporating such electronic devices, can be driven with low electric power while exhibiting high characteristics. The effect of reduced power consumption is particularly desirable for battery-driven devices such as cellular phones, game devices, toys and automobile parts.

### EXAMPLES

The present invention will now be explained in greater detail by examples and comparative examples, with the understanding that the present invention is in no way limited only to the examples.

### Example 1

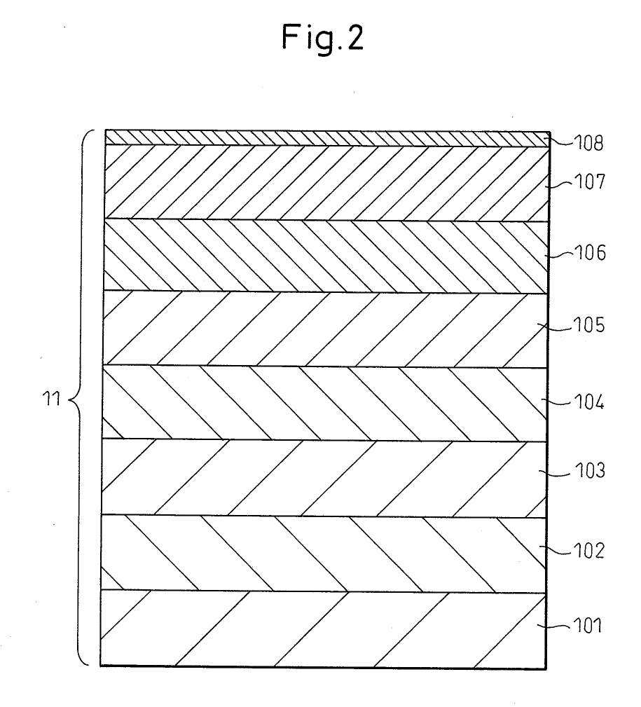

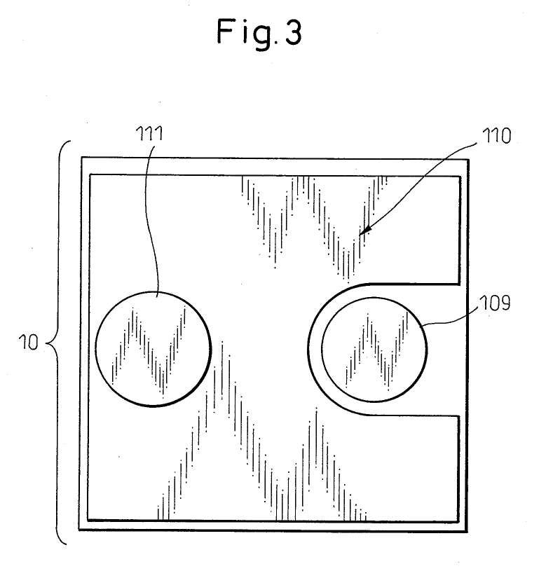

FIG. 2 is a cross-sectional schematic drawing of the epitaxial stacked structure 11 used in the LED 10 fabricated in the examples. FIG. 3 is a plan schematic drawing of the LED 10.

The stacked structure 11 was constructed with a substrate 101 comprising a sapphire c plane ((0001) crystal plane), over which were stacked an undoped GaN underlying layer (layer thickness=8 μm) 102, an Si-doped n-type GaN contact layer (layer thickness=2 μm, carrier concentration=5×10¹⁸ cm⁻³) 103, an Si-doped n-type In_{0.01}Ga_{0.99}N-clad layer (layer thickness=25 nm, carrier concentration=1×10¹⁸ cm⁻³) 104, a light emitting layer 105 with a multiple quantum structure comprising 6 Si-doped GaN barrier layers (layer thickness=14.0 nm, carrier concentration=1×10¹⁷ cm⁻³) and 5 undoped In_{0.20}Ga_{0.80}N well layers (layer thickness=2.5 nm), a Mg-doped p-type Al_{0.07}Ga_{0.93}N-clad layer (layer thickness=10 nm) 106 and a Mg-doped p-type Al_{0.02}Ga_{0.98}N contact layer (layer thickness=150 nm) 107, in that order via an AlN buffer layer (not shown). Each structural layer 102-107 of the stacked structure 11 was grown by an ordinary reduced pressure MOCVD process.

The Mg-doped p-type AlGaN contact layer 107 was grown by the following procedure.

(1) Upon completion of growth of the Mg-doped Al_{0.07}Ga_{0.93}N-clad layer 106, the pressure in the growth reactor was adjusted to 2×10⁴ Pascals (Pa). The carrier gas used was H₂.

(2) Using TMG, TMA and NH₃ as precursors and Cp₂Mg as the Mg doping material, vapor growth of the Mg-doped AlGaN layer was initiated at 1020° C.

(3) The TMG, TMA, NH₃ and Cp₂Mg were supplied continuously into the growth reactor over a period of 4 minutes to grow a Mg-doped Al_{0.02}Ga_{0.98}N layer to a layer thickness of 0.15 μm.

(4) Supply of the TMG, TMA and Cp₂Mg into the growth reactor was stopped to terminate growth of the Mg-doped Al_{0.02}Ga_{0.98}N layer.

Upon completion of vapor growth of the contact layer 107 composed of the Mg-doped AlGaN layer, the carrier gas was immediately switched from H₂ to N₂, the flow rate of NH₃ was reduced and the flow rate of the carrier gas nitrogen was increased by the amount of this reduction. Specifically, the NH₃ constituting 50% of the total circulating gas volume during growth was reduced to 0.2%. At the same time, supply of electricity to the high-frequency induction heating system used for heating of the substrate 101 was stopped.

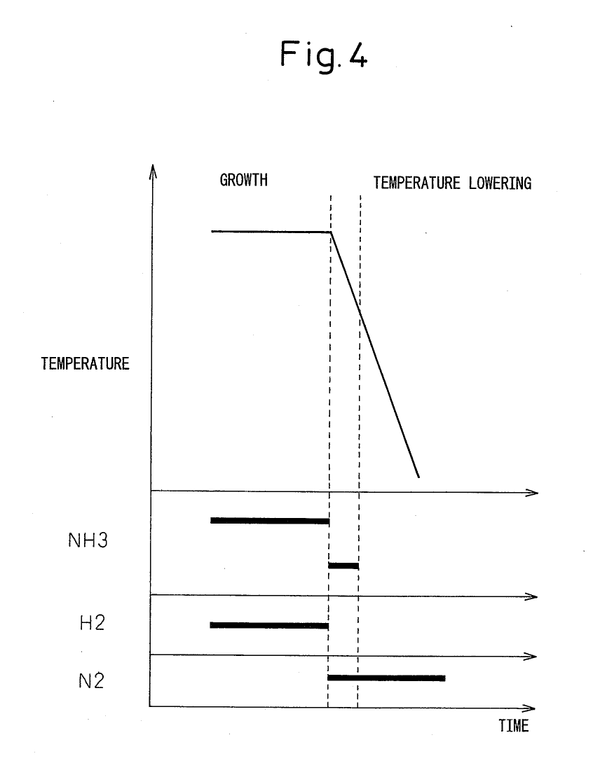

After holding for 2 minutes in this state, circulation of NH₃ was terminated. The temperature of the substrate was 850° C. FIG. 4 shows a graphical representation of the temperature lowering procedure.

After cooling to room temperature in this state, the stacked structure 11 was removed out from the growth reactor into air.

The atomic densities of magnesium and hydrogen in the contact layer 107 were quantified by SIMS analysis. The Mg atoms were at a density of 1.5×10²⁰ cm⁻³, and were distributed at roughly a fixed concentration in the direction of depth from the surface. On the other hand, hydrogen was present at a roughly fixed density of 7×10¹⁹ cm⁻³. The resistivity was estimated to be 150 Ωcm based on measurement by ordinary TLM.

The LED 10 shown in FIG. 3 was fabricated using an epitaxial stacked structure 11 provided with the aforementioned p-type contact layer. First, a positive electrode composed of ITO was formed on the p-type contact layer by sputtering. The following procedure was followed to form a conductive transparent oxide electrode layer made of ITO on a gallium nitride-based compound semiconductor.

A known photolithography technique and lift-off technique were used first to form a conductive transparent oxide electrode layer 110 made of ITO on a p-type AlGaN contact layer. For formation of the conductive transparent oxide electrode layer, first a substrate stacked with a gallium nitride-based compound semiconductor layer was placed in a sputtering apparatus, and after first forming ITO on the p-type AlGaN contact layer to a thickness of about 2 nm by RF sputtering, ITO was stacked thereover to a thickness of about 400 nm by DC sputtering. The pressure during RF film formation was approximately 1.0 Pa and the power supply was 0.5 kW. The pressure during DC film formation was approximately 0.8 Pa and the power supply was 0.5 kW.

The sputtering may be carried out under conditions appropriately selected from among publicly known conditions, using a known sputtering apparatus. The substrate stacked with the gallium nitride-based compound semiconductor layer is housed in a chamber. The interior of the chamber is evacuated to a degree of vacuum of 10⁻⁴-10⁻⁷ Pa. The sputtering gas used is He, Ne, Ar, Kr, Xe or the like. Ar is preferred from the viewpoint of availability. Discharge is carried out after adjusting the pressure to 0.1-10 Pa by introduction of one of these gases. The pressure is preferably set within the range of 0.2-5 Pa. The supplied electric power is preferably in the range of 0.2-2.0 kW. The discharge time and power supply can be adjusted to modify the thickness of the formed layer.

After forming the ITO film, it was subjected to annealing treatment for 1 minute at 800° C. in a nitrogen atmosphere containing 20% oxygen.

Upon completion of annealing treatment, ordinary dry etching was carried out on the region on which the negative electrode 109 was to be formed, and the surface of the Si-doped n-type GaN contact layer 103 was exposed at this region alone (see FIG. 3). Next, a first layer made of Cr (layer thickness=40 nm), a second layer made of Ti (layer thickness=100 nm) and a third layer made of Au (layer thickness=400 nm) were stacked in that order on a portion of the ITO film layer 110 and on the exposed Si-doped n-type GaN contact layer 103 by vacuum vapor deposition, to form a positive electrode bonding pad layer 111 and negative electrode 109.

After forming the bonding pad layer 111 and negative electrode 109, the back side of the sapphire substrate 101 was polished using a diamond fine particle abrasive, and given a final mirror surface finish. Next, the stacked structure 11 was cut and separated into discrete 350 μm square LEDs 10.

Next, chips were placed on a simple measuring lead frame (TO-18) and the negative electrode and positive electrode were each connected to the lead frame with gold (Au) wires.

A forward current was applied between the negative electrode 109 and positive electrode 110 of an LED chip mount fabricated by these steps, and the electrical and luminescent characteristics were evaluated. The forward driving voltage (Vf) with application of a 20 mA forward current was 3.0 V, and the reverse voltage (Vr) with a current of 10 μA was 20 V or more.

The wavelength of emitted light from the ITO electrode penetrating to the outside was 455 nm, and the light emission output measured with an ordinary integrating sphere was 15 mW. From a 5.1 cm (2 inch)-diameter wafer there were obtained 10,000 LEDs (excluding those with apparent defects), and the aforementioned characteristics were consistently exhibited.

In the same manner as these LEDs, there was also fabricated a stacked sample by RF sputtering of ITO to only 3 nm, and after annealing treatment for 1 minute, hard X-rays with an energy of 5948 eV were used for photoelectron spectroscopy from the ITO side in the SPring-8. The results are shown in FIGS. 5 and 6. For Ga, FIG. 5 confirms the presence of a component with a Ga—N bond and a component with a Ga—O bond. For N, FIG. 6 shows the presence of a component with an N—Ga bond as well as an N—O bond. That is, these results demonstrate the presence of a layer 108 containing a compound with a Ga—O bond and an N—O bond between the ITO layer and p-type AlGaN contact layer. The thickness of the layer containing the compound with a Ga—O bond and an N—O bond was measured to be 5.3 nm by the method described above, based on FIG. 5.

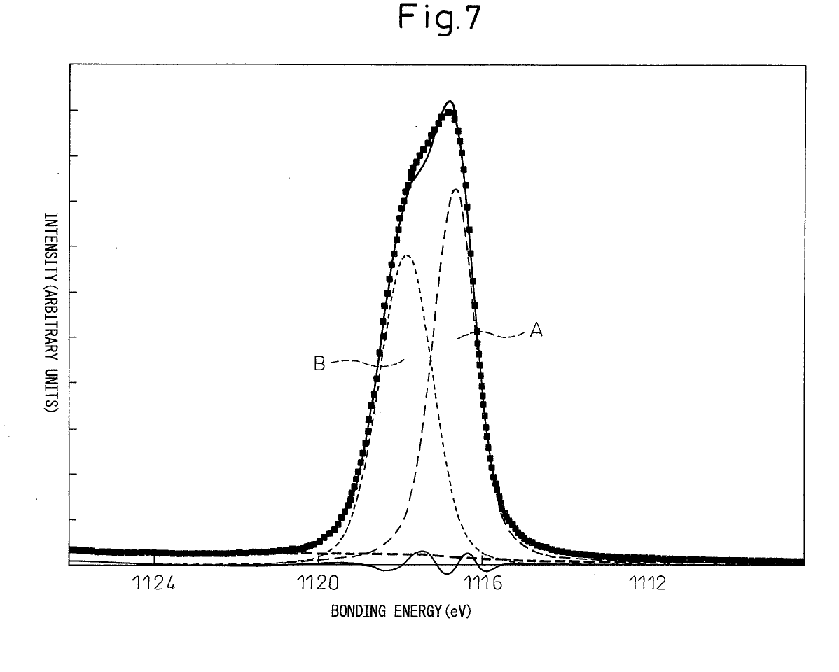

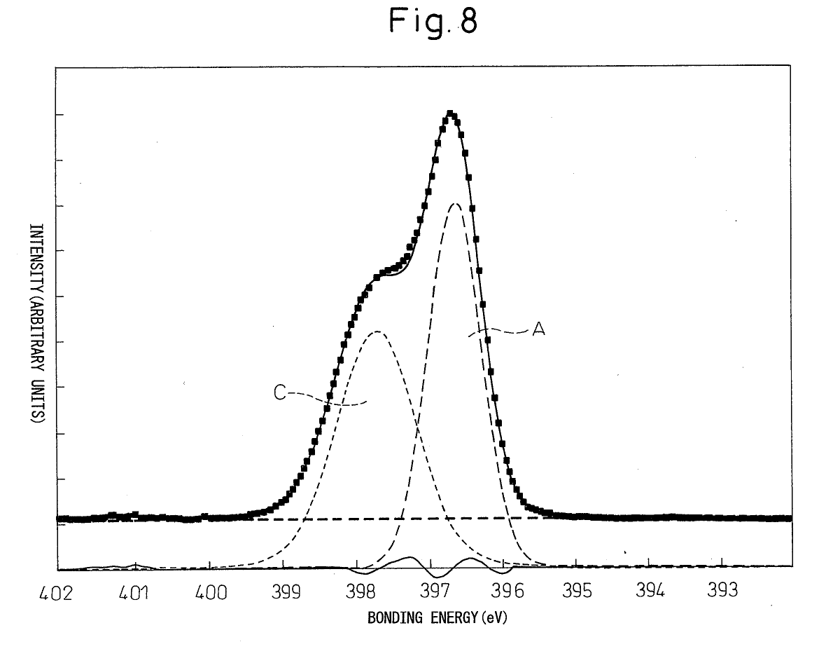

Separately, the stacked structure 11 removed from the growth reactor was measured by photoelectron spectroscopy from the p-type AlGaN contact layer 107 side, using hard X-rays with an energy of 5948 eV in the SPring-8. The results are shown in FIGS. 7 and 8. For Ga, FIG. 7 confirms the presence of a component with Ga—N bonds and a component with Ga—O bonds. For N, FIG. 8 shows the presence of a component with an N—Ga bond as well as an N—O bond. The layer 108 containing the compound with a Ga—O bond and an N—O bond was present at this stage.

### Example 2

A stacked structure for Example 2 was formed under the same film forming conditions as Example 1.

However, during the step of lowering the temperature after forming the p-type contact layer, the gas phase atmosphere was composed of hydrogen and the amount of ammonia was not reduced.

The LED 10 was fabricated using an epitaxial stacked structure 11 provided with the aforementioned p-type contact layer. The method of forming the electrode was also according to Example 1. That is, after forming the ITO film, it was subjected to annealing treatment for 1 minute at 800° C. in a nitrogen atmosphere containing 20% oxygen.

A forward current was applied between the negative electrode 109 and positive electrode 110 of an LED chip fabricated by these steps, and the electrical and luminescent characteristics were evaluated. The forward driving voltage (Vf) with application of a 20 mA forward current was 3.05 V, and the reverse voltage (Vr) with a current of 10 μA was 20 V or more.

The wavelength of emitted light from the ITO electrode penetrating to the outside was 455 nm, and the light emission output measured with an ordinary integrating sphere was 15.5 mW. From a 5.1 cm (2 inch)-diameter wafer there were obtained 10,000 LEDs (excluding those with apparent defects), and the aforementioned characteristics were consistently exhibited.

In the same manner as these LEDs, there was also fabricated a stacked sample by RF sputtering of ITO to only 3 nm, and after annealing treatment for 1 minute, hard X-rays with an energy of 5948 eV were used for photoelectron spectroscopy from the ITO side in the SPring-8. These results confirmed the presence of a layer 108 containing a compound with a Ga—O bond and an N—O bond between the ITO layer and p-type AlGaN contact layer.

### Comparative Example 1

A stacked structure for Comparative Example 1 was formed under the same film forming conditions as Example 1.

However, during the step of lowering the temperature after forming the p-type contact layer, the gas phase atmosphere was composed of hydrogen and the amount of ammonia was not reduced. After removal from the MOCVD furnace, a separate lamp-heated rapid thermal annealing furnace was used for heat treatment for 30 seconds at 900° C. in a nitrogen atmosphere. Upon completion of the heat treatment, it was allowed to stand in a nitrogen atmosphere and the temperature was lowered to room temperature. It was then allowed to stand in the furnace for about 1 hour thereafter.

The LED 10 was fabricated using an epitaxial stacked structure 11 provided with the aforementioned p-type contact layer. The method of forming the electrode was also according to Example 1. However, no heat treatment was carried out after forming the ITO film.

A forward current was applied between the negative electrode 109 and positive electrode 110 of an LED chip fabricated by these steps, and the electrical and luminescent characteristics were evaluated. The forward driving voltage (Vf) with application of a forward current of 20 mA was 3.6 V, which was significantly higher than Example 1 or 2. The reverse voltage (Vr) with a current of 10 μA was 20 V or more.

The wavelength of emitted light from the ITO electrode penetrating to the outside was 455 nm, and the light emission output measured with an ordinary integrating sphere was 13 mW. From a 5.1 cm (2 inch)-diameter wafer there were obtained 10,000 LEDs (excluding those with apparent defects), and the aforementioned characteristics were consistently exhibited.

In the same manner as these LEDs, there was also fabricated a stacked sample by RF sputtering of ITO to only 3 nm, and hard X-rays with an energy of 5948 eV were used for photoelectron spectroscopy from the ITO side in the SPring-8. As a result, only a component with a Ga—N bond for Ga and a component with an N—Ga bond for N were found to be present.

### INDUSTRIAL APPLICABILITY

A gallium nitride-based compound semiconductor light emitting device according to the present invention has satisfactory light emission output and low driving voltage, and is therefore of very high industrial value.

1. A gallium nitride-based compound semiconductor light emitting device comprising an n-type semiconductor layer, a light emitting layer and a p-type semiconductor layer, composed of gallium nitride-based compound semiconductors, in that order on a substrate, the n-type semiconductor layer and p-type semiconductor layer being provided with an negative electrode and positive electrode, respectively, and the positive electrode being composed of a conductive and transparent oxide material, the light emitting device being characterized in that a layer containing a compound with a Ga—O bond and/or an N—O bond is situated between the p-type semiconductor layer and the positive electrode.

2. A gallium nitride-based compound semiconductor light emitting device according to claim 1, wherein the oxide material is at least one type selected from the group consisting of ITO, IZO, AZO and ZnO.

3. A process for production of a gallium nitride-based compound semiconductor light emitting device wherein a gallium nitride-based compound semiconductor light emitting device is produced by forming an n-type semiconductor layer, a light emitting layer and a p-type semiconductor layer, composed of gallium nitride-based compound semiconductors, in that order on a substrate, and forming an negative electrode and positive electrode composed of a conductive and transparent oxide material, on the formed n-type semiconductor layer and p-type semiconductor layer, respectively, the process being characterized by comprising a step of producing a layer containing a compound with a Ga—O bond and/or an N—O bond on the surface of the p-type semiconductor layer, after the step of forming the positive electrode.

4. A process for production of a gallium nitride-based compound semiconductor light emitting device according to claim 3, wherein the step of producing a layer containing a compound with a Ga—O bond and/or an N—O bond on the surface of the p-type semiconductor layer is heat treatment at a temperature of 300° C. or higher.

5. A process for production of a gallium nitride-based compound semiconductor light emitting device according to claim 4, wherein the heat treatment is carried out in an oxygen-containing atmosphere.

6. A process for production of a gallium nitride-based compound semiconductor light emitting device wherein a gallium nitride-based compound semiconductor light emitting device is produced by forming an n-type semiconductor layer, a light emitting layer and a p-type semiconductor layer, composed of gallium nitride-based compound semiconductors, in that order on a substrate, and forming an negative electrode and positive electrode composed of a conductive and transparent oxide material, on the formed n-type semiconductor layer and p-type semiconductor layer, respectively, the process being characterized by comprising a step of producing a layer containing a compound with a Ga—O bond and/or an N—O bond on the surface of the p-type semiconductor layer, after the step of forming the p-type semiconductor layer and before the step of forming the positive electrode.

7. A process for production of a gallium nitride-based compound semiconductor light emitting device according to claim 6, wherein the step of producing a layer containing a compound with a Ga—O bond and/or an N—O bond on the surface of the p-type semiconductor layer comprises heat treatment for at least 1 minute at a temperature of 700° C. or higher in an ammonia-free atmosphere, and exposure to an oxygen-containing atmosphere either during or after the heat treatment.

8. A process for production of a gallium nitride-based compound semiconductor light emitting device according to claim 7, wherein the heat treatment is carried out for at least 5 minutes.

9. A process for production of a gallium nitride-based compound semiconductor light emitting device according to claim 6, wherein the step of producing a layer containing a compound with a Ga—O bond and/or an N—O bond on the surface of the p-type semiconductor layer is a step of lowering the temperature after formation of the p-type semiconductor layer, where the carrier gas is composed of a gas other than hydrogen, the temperature is lowered in an atmosphere containing no introduced ammonia, and the step is followed by exposure to an oxygen-containing atmosphere.

10. A lamp comprising a gallium nitride-based compound semiconductor light emitting device according to claim 1.

11. An electronic device incorporating a lamp according to claim 10.

12. A machine incorporating an electronic device according to claim 11.
